(19) United States
(12) Patent Application Publication
(10) Pub. No.: US 2009/0201641 A1
(43) Pub. Date: Aug. 13, 2009

(54) Airflow conducting structure

(75) Inventors: Guang-Liang Guo, Shanhai City (CN); Wen-Jie Liu, Shanhai City (CN); Tsai-Kuei Cheng, Taipei City (TW)

Correspondence Address: Edwards Angell Palmer & Dodge LLP, P.O. Box 55874, Boston, MA, 02205, US

(73) Assignee: Inventec Corporation, Taipei City (TW)

(21) Appl. No.: 12/069,846

(22) Filed: Feb. 13, 2008

(51) Int. Cl. H05K 7/20

(52) U.S. Cl. 361/694

(57) ABSTRACT

The present invention provides an airflow conducting structure for an electronic device having a base and a control box. The control box is inserted in and mounted on the base, and a first connection section is disposed in a grooved top of the base. The control box has a box body, a heat generating source disposed in the box body, and a second connection section disposed on the bottom of the box body for being connected to the first connection section. The airflow conducting structure includes airflow inlets and airflow outlets that are respectively disposed on the base and the control box, so as to form a chimney-like airway. Therefore, a better heat dissipating efficiency is achieved without increasing the volume of the electronic device.

### BACKGROUND OF THE INVENTION

1. Field of the Invention

The present invention relates to an airflow conducting technique, and more particularly to an airflow conducting structure for electronic devices.

2. Description of Related Art

The heat dissipating problem of an electronic device has become a major factor for deciding the performance and quality of an electronic device. In a sort of electronic devices, a heat dissipating system that has a better heat dissipating capability is undoubtedly more popular. While designing an electronic device, designs for the interior and the exterior of the electronic device are correspondingly taken into consideration for enhancing heat dissipating efficiency.

In a conventional method for heat dissipation, a heat dissipating unit such as heat sink, heat pipe, fan, and the like is installed at a position where corresponds to the heat generating source in an electronic device, and a heat dissipating hole corresponding to the abovementioned heat dissipating unit is set up on a casing of the electronic device so as to perform forced convection for dissipating heat, which generated by the heat generating source.

Taking electronic devices such as audio/video device, thin client computer, and the like for example, the volume of the electronic device is required as small as possible for the purpose of portability. However, if the above conventional heat dissipating method is used, the volume of the electronic device must be increased. On the contrary, if a smaller heat dissipating unit is used, space-saving can be achieved, but the cost will be increased, more interior components in the electronic device are needed, and the structure is relatively getting complicated.

Hence, it is desired to provide an airflow conducting technique so as to provide a better heat dissipating effect without increasing the volume of the electronic device and thus overcome the drawbacks of the prior art.

### SUMMARY OF THE INVENTION

In view of the disadvantages of the prior art mentioned above, it is an objective of the present invention to provide an airflow conducting structure, which provides a better heat dissipating efficiency without increasing the volume of a device.

It is another objective of the present invention to provide an airflow conducting structure for lowering the cost of heat dissipation.

To achieve the aforementioned and other objectives, the present invention provides an airflow conducting structure for an electronic device, which has a base and a control box. The control box is inserted in and mounted on the base and a first connection section is disposed in a grooved top of the base. The control box has a box body, a heat generating source disposed in the box body, and a second connection section disposed on the bottom of the box body and connected to the first connection section. The airflow conducting structure includes a first airflow inlet disposed on the base; a first airflow outlet disposed on the first connection section and connected to the first airflow inlet for conducting airflow to the first airflow outlet through the first airflow inlet, so that the airflow flows upward and from the first airflow outlet; a second airflow inlet corresponding to the first airflow outlet, disposed on the second connection section and connected to the first airflow outlet for conducting the airflow from the first airflow outlet to flow upward; and a second airflow outlet disposed on the box body and above the heat generating source and connected to the second airflow inlet, so that the airflow is discharged through the second airflow outlet.

The abovementioned airflow conducting structure further includes a third airflow inlet disposed on the box body. The third airflow inlet is disposed between the second airflow outlet and the second airflow inlet and below the heat generating source, and the third airflow inlet can be selectively connected to the second airflow inlet and/or the second airflow outlet. In addition, in one embodiment, only airflow conducting technique of natural convection is used. In other embodiments, a heat dissipating unit disposed on the base can be used for performing forced convection.

In one embodiment, the first airflow outlet is disposed on the front side of the first connection section, the second airflow inlet is disposed on the front side of the second connection section, the second airflow outlet is disposed on the top of the box body, and the third airflow inlet is disposed on the front side of the box body. In other embodiments, the first airflow outlet can be disposed on the front and back sides of the first connection section, the second airflow inlet can also be disposed on the front and back sides of the second connection section, and the third airflow inlet can be disposed on the front and back sides of the box body while as long as the second airflow outlet is disposed above the heat generating source. Certainly, those skilled in the art can modify positions and the number of the aforesaid airflow inlets and airflow outlets based on the practical demand.

Compared with the prior art, the airflow conducting structure of the present invention provides a chimney-like airway by disposing airflow inlets and airflow outlets on the base and the control box of the electronic device, so that the objective of heat dissipation is achieved based on the principle that hot air is lighter than cold air to conduct the airflow through the base and the control box of the electronic device. Accordingly, a better heat dissipating efficiency is achieved without increasing the overall volume of the electronic device. In addition, since the present invention omits some heat dissipating units and provide a better heat dissipating efficiency, the components and the cost required for heat dissipation can be relatively decreased.

### BRIEF DESCRIPTION OF THE DRAWINGS

The present invention can be more fully understood by reading the following detailed description of the preferred embodiments, with reference made to the accompanying drawings, wherein:

FIG. 1 is an exploded view showing the airflow conducting structure for an electronic device according to an embodiment of the present invention;

FIG. 2A is an exploded view showing the airflow conducting structure for an electronic device according to another embodiment of the present invention applied to;

FIG. 2B is a schematic diagram showing the state of the airflow conduction in the airflow conducting structure of FIG. 2A; and

FIG. 3 is a schematic diagram showing the airflow conducting structure according to another embodiment of the present invention.

### DETAILED DESCRIPTION OF THE PREFERRED EMBODIMENTS

The following illustrative embodiments are provided to illustrate the disclosure of the present invention. These and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

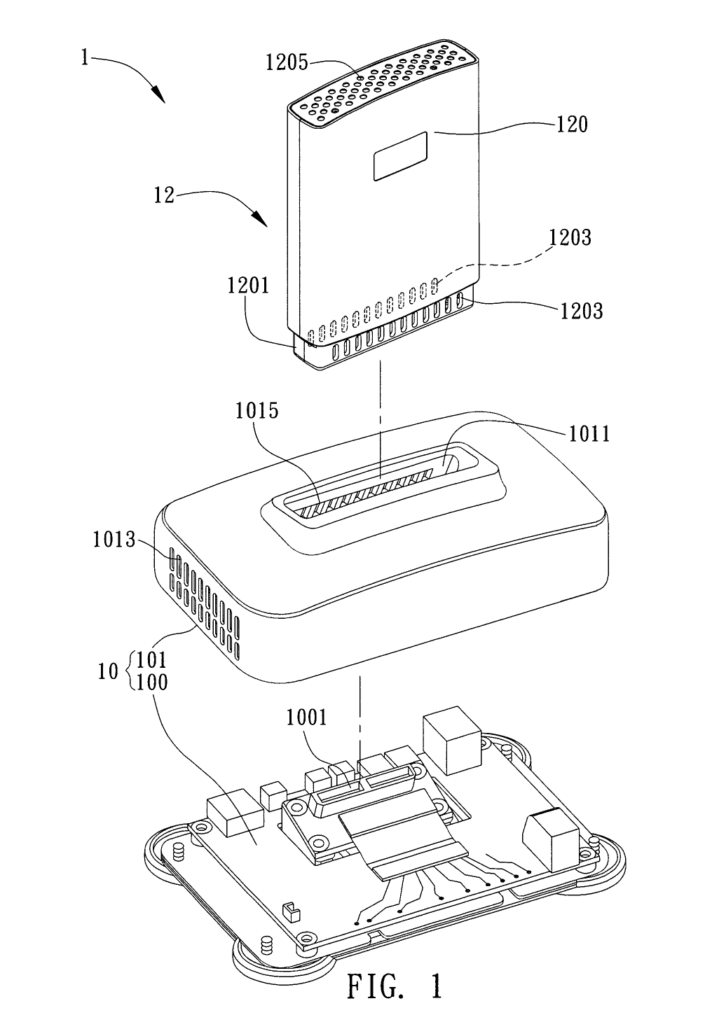

Referring to FIG. 1, it is an exploded view showing the airflow conducting structure of the present invention. It should also be noted that all illustrated drawings are simplified and are for illustrating elements related to the present invention only. These elements are not shown based on the practical ratio, number, shape, and size. In practice, the number, shape, and size can be varied, and the layout of these elements can be more complicated.

As shown in the FIG. 1, the present invention is used in an electronic device such as audio/video device 1. The audio/video device 1 has a base 10 and a control box 12, which is inserted in and mounted on the base 10. The control box can be slantwise mounted on the base 12 for example, but not limited to it. In addition, the electronic device can also be a computer or other electronic devices.

The base 10 includes a base plate 100 and a base cover 101 that covers the base plate 100. The base plate 100 has a connection port 1001 disposed thereon, and the base cover 101 has a first connection section 1011 disposed in its grooved top, and the first connection section 1011 is disposed correspondingly to the connection port 1001. The control box 12 includes a box body 120, a heat generating source (not shown in the FIG.) disposed in the box body 120, and a second connection section 1201 disposed on the bottom of the box body 120. The second connection section 1201 is used for being connected to the first connection section 1011. After the first connection section 1011 and the second connection section 1201 are connected to each other, the control box 12 is electrically connected to the connection port 1001.

The control box 12 can be an external connection box. It should be understood that a control mechanism of the electronic device can be disposed on the base 10 and/or in the control box 12, and is not limited to that as stated in the above example.

The airflow conducting structure includes a first airflow inlet 1013 disposed on the base 10, a first airflow outlet 1015 disposed on the first connection section 1011, a second airflow inlet 1203 that is disposed on the second connection section 1201 and corresponding to the first airflow outlet 1015, and a second airflow outlet 1205 disposed on the box body 120.

In this embodiment, the first airflow inlet 1013 is disposed on one side (for instance, left side) of the base cover 101 of the base 10, and is an opening, for instance. However, the first airflow inlet 1013 is not limited to this position, arrangement, and shape. In other words, the position and shape of the first airflow inlet 1013 can be modified. For example, the first airflow inlet 1013 can be disposed on the right side, the front side, or the top of the base 10.

The first airflow outlet 1015 is disposed on the front side of the first connection section 1011. After the first connection section 1011 and the second connection section 1201 are connected to each other, the first airflow outlet 1015 and the first airflow inlet 1013 are connected to each other for conducting airflow to the first airflow outlet 1015 through the first airflow inlet 1013, so that the airflow flows upward and from the first airflow outlet 1015. In this embodiment, the first airflow outlet 1015 is an opening, for example, but the arrangement and shape of the openings are not limited to that as illustrated herein.

The second airflow inlet 1203 is connected to the first airflow outlet 1015 for conducting the airflow from the first airflow outlet 1015 to flow upward. In this embodiment, the second airflow inlet 1203 includes an opening corresponding to the first airflow outlet 1015. After the first connection section 1011 and the second connection section 1201 are connected to each other, the second airflow inlet 1203 and the first airflow outlet 1015 are connected to each other.

The second airflow outlet 1205 is connected to the second airflow inlet 1203. The heat generating source disposed in the box body 120 is disposed between the second airflow outlet 1205 and the second airflow inlet 1203, so that the airflow from the base 10 passes through the heat generating source and is discharged through the second airflow outlet 1205. In this embodiment, the second airflow outlet 1205 is located above the heat generating source and disposed on the top of the box body 120. In other words, the heat generating source is disposed on the airway between the second airflow outlet 1205 and the second airflow inlet 1203. The second airflow outlet 1205 may include a plurality of openings, and the arrangement and shape of the openings can be modified based on the practical need.

Accordingly, the airflow can be conducted to pass through the base 10 and the control box 12 of the audio/video device 1, and is discharged through the second airflow outlet 1205 after passing through the heat generating source based on the principle that hot air is lighter than cold air. It should be noted that cold/hot air convection is a way of heat conduction and is well understood by those in the art. Therefore, there is no need of detailed description herein.

Except that the position, arrangement, and shape of the abovementioned airflow inlets and airflow outlets can be modified, there are other variations as well.

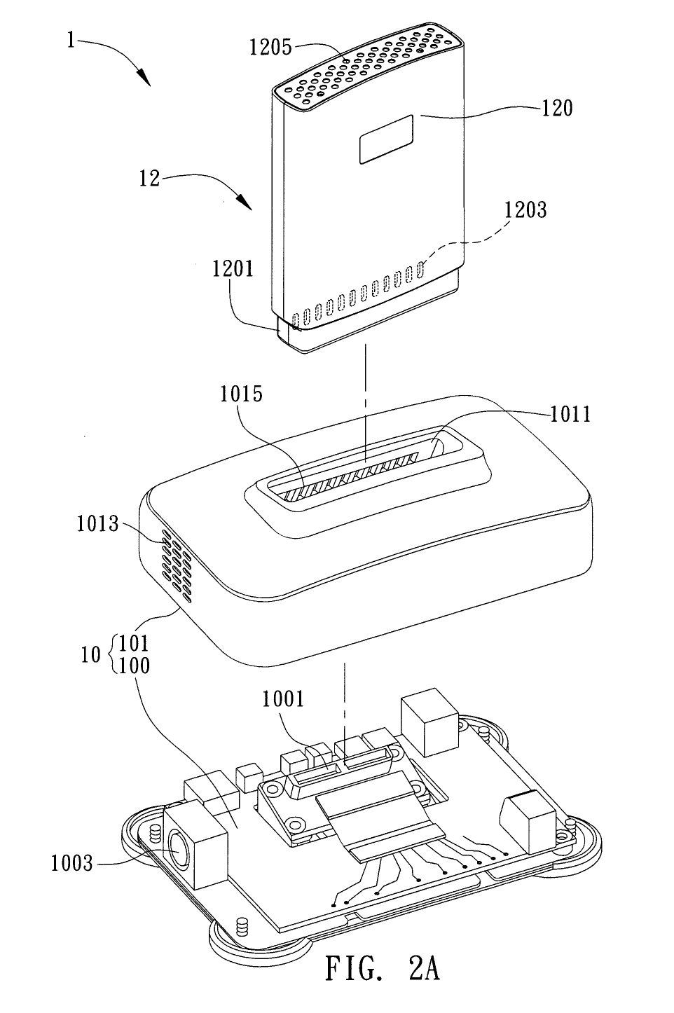

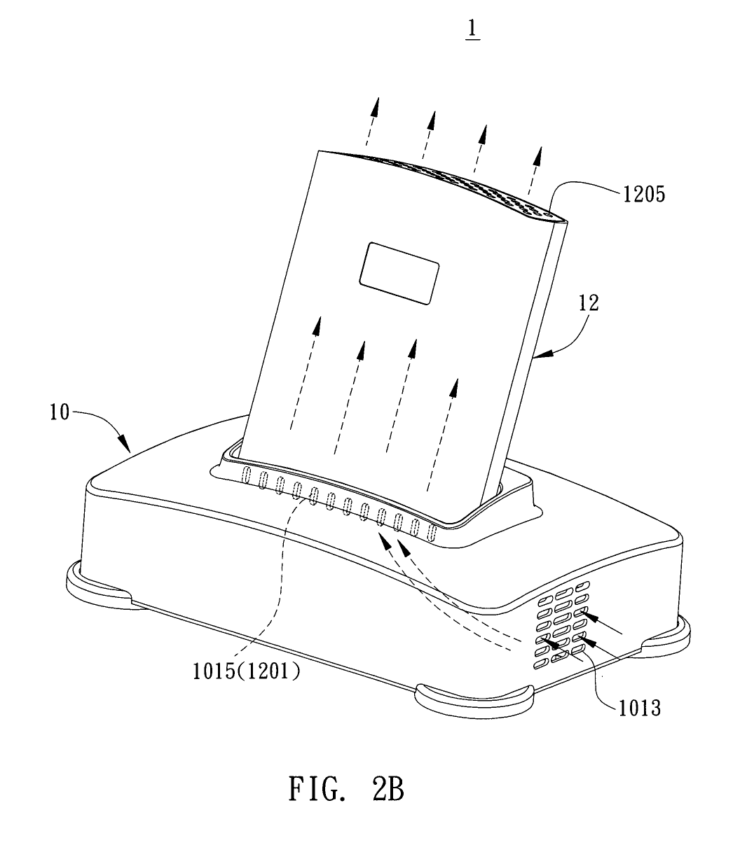

As shown in FIG. 2A, a heat dissipating unit 1003 such as fan can be disposed on one side of the base plate 100 of the base 10 for performing forced convection so as to increase airflow fluidity and enhance heat dissipating efficiency. Accordingly, the first airflow inlet 1013 corresponding to the position of the heat dissipating unit 1003 is disposed on the base cover 101. In other words, it is understood by those in the art that the position of the first airflow inlet 1013 can also be changed accordingly when the position of the heat dissipating unit 1003 is changed.

As indicated by arrows in FIG. 2B, when the control box 12 is inserted in and mounted on the base 10, the first airflow outlet 1015 is connected to the first airflow inlet 1013 for conducting airflow to pass through the first airflow inlet 1013 to the first airflow outlet 1015, so that the airflow flows upward and from the first airflow outlet 1015. The second airflow inlet 1203 is connected to the first airflow outlet 1015 for conducting the airflow from the first airflow flow outlet 1015 to flow upward. Finally, the second airflow outlet 1205 is connected to the second airflow inlet 1203, so as to form a chimney-like airway and achieve heat dissipation. In addition, in a modified example with a heat dissipating unit 1003, the heat dissipating unit 1003 can perform the forced convection. It should be understood that the heat dissipation can also be achieved without disposing the heat dissipating unit 1003.

Referring to FIGS. 1 and 2A, no heat dissipating unit is disposed and natural convection is performed as shown in FIG. 1. Therefore, more and/or bigger openings are formed as the first airflow inlets 1013. The first airflow outlets 1015 are disposed on the front and back sides of the first connection section 1011 (only the first airflow outlet 1015 on the front side is shown in FIG. 1), and the second airflow inlets 1203 are also disposed on the front and back sides of the second connection section 1201 so as to achieve the heat dissipation as well. In addition, as shown in FIG. 2A, a heat dissipating unit 1003 is disposed and, thus forced convection is performed. Therefore, less and/or smaller openings are formed as the first airflow inlets 1013. The first airflow outlets 1015 are disposed on the front side of the first connection section 1011, and the second airflow inlets 1203 are also disposed on the front side of the second connection section 1201. However, it should be understood that when the heat dissipating unit 1003 is disposed, the first airflow inlet 1013, the first airflow outlet 1015 and/or the second airflow inlet 1203 shown in FIG. 1 can also be used and are not limited to those shown in FIG. 2A. For example, when the heat dissipating unit 1003 is disposed, the position of the first airflow inlet 1013 can be higher than that of the first airflow outlet 1015.

Further, the present invention has, but is not limited to following variations.

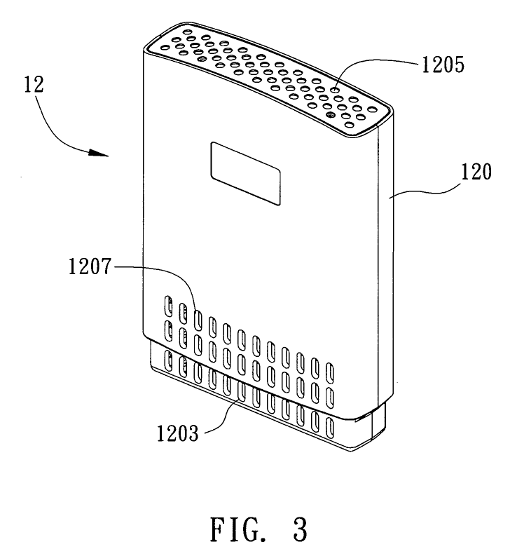

As shown in FIG. 3, the airflow conducting structure in another embodiment of the present invention includes third airflow inlets 1207 disposed on the box body 120 of the control box 12, wherein the third airflow inlets 1207 are disposed below the heat generating source. As shown in FIG. 3, the third airflow inlets 1207 are disposed above the second airflow inlets 1203, and are connected to the second airflow inlet 1203. Certainly, the position and shape of the third airflow inlet 1207 are not limited to that stated herein. As long as the third airflow inlets 1207 are disposed between the second airflow outlet 1205 and the second airflow inlet 1203, the third airflow inlets 1207 can be selectively connected to the second airflow inlet 1203 and/or the second airflow outlets 1205. Moreover, the heat dissipating efficiency can be enhanced by increasing the number of the airflow inlets disposed on the control box 12.

Certainly, the airflow inlets and airflow outlets of the aforesaid embodiments can be replaced or modified for those in the art. For example, the third airflow inlet 1207 may be disposed in the structure shown in FIG. 1. The heat dissipating unit 1003 may be disposed in an electronic device formed with the third airflow inlet 1207 and the first airflow inlet 1013 corresponding to the heat dissipating unit 1003. The third airflow inlet 1207 and the heat dissipating unit 1003 may be disposed in the structure shown in FIG. 1. In other words, the airflow conducting structure of the embodiments in the present invention can be flexibly changed and modified based on the airflow conducting technique of the present invention.

In conclusion, the airflow conducting structure of the present invention can be disposed with the airflow inlets and airflow outlets according to the structures of the base and the control box of the electronic device, so as to form a chimney-like airway for enhancing the heat dissipating efficiency. Compared with the prior art, the present invention provides the airflow conducting structure modified from the electronic device, and therefore provides a better heat dissipating efficiency without increasing the volume of the electronic device. In addition, since the present invention omits some components relative to heat dissipation in the prior art, and thereby comparatively saves the cost of the related components, so that the cost of heat dissipation is lowered.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. An airflow conducting structure for an electronic device having a base and a control box, wherein the control box is inserted in and mounted on the base that has a groove top and a first connection section disposed in the groove top, and the control box has a box body, a heat generating source disposed in the box body and a second connection section disposed on a bottom of the box body and connected to the first connection section, the airflow conducting structure comprising:
a first airflow inlet disposed on the base;
a first airflow outlet disposed on the first connection section and connected to the first airflow inlet for conducting airflow to the first airflow outlet through the first airflow inlet, so that the airflow flows upward and from the first airflow outlet;
a second airflow inlet corresponding to the first airflow outlet, disposed on the second connection section and connected to the first airflow outlet for conducting the airflow from the first airflow outlet to flow upward; and
a second airflow outlet disposed on the box body and the heat generating source, and connected to the second airflow inlet, so that the airflow is discharged through the second airflow outlet.

2. The airflow conducting structure of claim 1, wherein the first airflow outlet is disposed on a front side of the first connection section.

3. The airflow conducting structure of claim 1, wherein the first airflow outlet is disposed on front and back sides of the first connection section.

4. The airflow conducting structure of claim 3, wherein the second airflow inlet is disposed on front and back sides of the second connection section.

5. The airflow conducting structure of claim 1, wherein the second airflow inlet is disposed on a front side of the second connection section.

6. The airflow conducting structure of claim 1, further comprising a third airflow inlet disposed on the box body, and between the second airflow inlet and the second airflow outlet.

7. The airflow conducting structure of claim 6, wherein the third airflow inlet is connected to the second airflow inlet.

8. The airflow conducting structure of claim 6, wherein the third airflow inlet is connected to the second airflow outlet.

9. The airflow conducting structure of claim 6, wherein the third airflow inlet is disposed on the front side of the box body.

10. The airflow conducting structure of claim 6, wherein the third airflow inlet is disposed on front and back sides of the box body.

11. The airflow conducting structure of claim 6, wherein the third airflow inlet is located below the heat generating source.

12. The airflow conducting structure of claim 1, wherein the second airflow outlet is disposed on a top of the box body.

13. The airflow conducting structure of claim 1, further comprising a heat dissipating unit disposed on the base for performing forced convection.
